(19) United States
(12) Patent Application Publication
(10) Pub. No.: US 2025/0047061 A1
(43) Pub. Date: Feb. 6, 2025

(54) CO-PACKAGED PHOTONICS DRIVER

(71) Applicant: MaxLinear, Inc., Carlsbad, CA (US)

(72) Inventors: Abdelkrim El Amili, San Diego, CA (US); Mario Milicevic, Irvine, CA (US); Curtis Ling, Carlsbad, CA (US)

(73) Assignee: MaxLinear, Inc., Carlsbad, CA (US)

(21) Appl. No.: 18/791,337

(22) Filed: Jul. 31, 2024

Related U.S. Application Data
(60) Provisional application No. 63/516,856, filed on Jul. 31, 2023.
(60) Provisional application No. 63/590,336, filed on Oct. 13, 2023.

(51) Int. Cl. H01S 5/026; H01S 5/02345

(52) U.S. Cl. CPC H01S 5/0265; H01S 5/02345

(57) ABSTRACT

A co-packaged photonics device includes a photonics device and a photonics driver. The photonics device has an intrinsic impedance and the photonics device is attached to a substrate. The photonics driver is attached to the substrate and is adjacent to the photonics device. The photonics driver includes one or more electrical connections with the photonics device. The photonics driver is configured to drive the photonics device at the intrinsic impedance.

### CROSS REFERENCE TO RELATED APPLICATIONS

This U.S. Patent application claims priority to U.S. Provisional Patent Applications No. 63/516,856, titled “COPACKAGED PHOTONICS DRIVER,” and filed on Jul. 31, 2023, and No. 63/590,336, titled “COPACKAGED PHOTONICS DRIVER,” and filed on Oct. 13, 2023, the disclosure of which are hereby incorporated by reference in their entirety.

### TECHNICAL FIELD

This disclosure generally relates to a photonics device, and more specifically, to a co-packaged photonics driver.

### BACKGROUND

Unless otherwise indicated herein, the materials described herein are not prior art to the claims in the present application and are not admitted to be prior art by inclusion in this section.

Optical transceivers for datacenter applications operate at symbol rates in the 56-112 gigabaud (GBd) range. A common way to transmit optical signals at these speeds is to use high-speed electronic circuits to drive the modulator terminal of a high-speed electro-optical device called an electro-absorptive modulated laser (EML), thereby converting an electrical signal to one carried by laser light. An EML is typically driven by a driver device.

The subject matter claimed in the present disclosure is not limited to implementations that solve any disadvantages or that operate only in environments such as those described above. Rather, this background is only provided to illustrate one example technology area where some implementations described in the present disclosure may be practiced.

### SUMMARY

In an example embodiment, a co-packaged photonics device may include a photonics device and a photonics driver. The photonics device may have an intrinsic impedance and may be attached to a substrate. The photonics driver may be disposed on a driver die and may be attached to the substrate adjacent to the photonics device. The photonics driver may include one or more electrical connections with the photonics device. The photonics driver may be configured to drive the photonics device at the intrinsic impedance.

In another embodiment, a co-packaged photonics device may include a substrate, a first die, a second die, and a third die. The first die may be attached to the substrate and may have a first photonics device disposed thereon. The first photonics device may have a first intrinsic impedance. The second die may be attached to the substrate and may have a second photonics device disposed thereon. The second photonics device may have a second intrinsic impedance. The third die may be attached to the substrate and may be adjacent to the first die and the second die. The third die may have a first photonics driver and a second photonics driver disposed thereon. The first photonics driver may be configured to drive the first photonics device at the first intrinsic impedance and the second photonics driver may be configured to drive the second photonics device at the second intrinsic impedance.

In another embodiment, a method may include obtaining, by a photonics driver, an electrical signal to be transmitted to a remote device. The method may also include conveying the electrical signal to a photonics device using a bond wire connecting the photonics driver to the photonics device. The photonics driver and the photonics device may be adjacently attached to a substrate and the photonics driver may be configured to drive the photonics device at an intrinsic impedance of the photonics device. The method may further include transmitting an optical signal from the photonics device to the remote device.

The objects and advantages of the embodiments will be realized and achieved at least by the elements, features, and combinations particularly pointed out in the claims.

Both the foregoing general description and the following detailed description are given as examples and are explanatory and not restrictive of the invention, as claimed.

### DESCRIPTION OF DRAWINGS

Example implementations will be described and explained with additional specificity and detail using the accompanying drawings in which:

FIG. 1 illustrates an example co-packaged photonics device;

FIG. 2 illustrates another example co-packaged photonics device;

FIG. 3 illustrates a another example co-packaged photonics device;

FIGS. 4A and 4B illustrate two views of an example co-packaged photonics device; and

FIG. 5 illustrates a flowchart of an example method of signal transmission using a co-packaged photonics device.

### DETAILED DESCRIPTION

An electro-absorptive modulated laser (EML) device may include a distributed feedback (DFB) laser, where an output from the DFB laser may be coupled to an electro-absorptive (EA) modulator. In instances in which a modulated signal is applied to the EA modulator, an absorption associated with the EA modulator may be modulated, which may be in a non-linear manner, which may produce a modulated laser output.

In some prior approaches, the EML device may be mounted to a substrate (e.g., a metallized aluminum nitride substrate) along with some other passive electrical components including various resistors and/or capacitors. The modulator used in such devices may exhibit an impedance to ground that may be approximately 80-100 ohms. Alternatively, or additionally, a transmission line used to deliver high speed signals from a driver device (that may be located some distance away from the EML device) to the EML device may include a standard transmission line impedance, which may be approximately 50 ohms. In some instances, in response to signals being transmitted to/from the EML device, signal reflections may appear at a junction between the EML device and the transmission line. Some prior approaches attempt to avoid or remove the signal reflections by including a matching resistor connected to ground in shunt with the EA modulator, which may be referred to as brute force impedance matching. While brute force impedance matching may be effective at causing a broadband impedance match at the EML device, the brute force matching may introduce inefficiencies, including inefficiency in the driver device due in part to power dissipated in the matching resistor.

Aspects of the present disclosure address these and other limitations of prior approaches by co-packaging a photonics device and a photonics driver. A co-packaged photonics device (e.g., that includes a photonics device and a photonics driver) may be arranged such that the photonics driver may be adjacent to the photonics device, such that the matching resistor may be eliminated from the co-packaged photonics device. Alternatively, or additionally, the adjacency of the photonics device and the photonics driver may minimize a length of bond wires between the photonics device and the photonics driver, such that the bond wire length may be shorter than one wavelength of an electrical signal between the photonics device and the photonics driver.

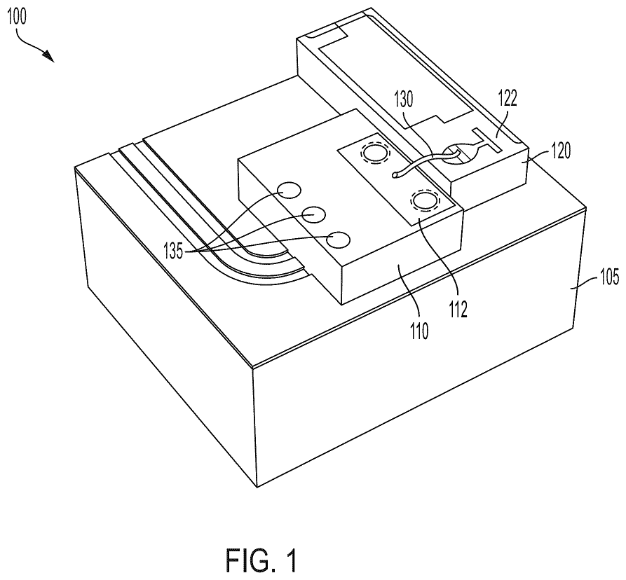

FIG. 1 illustrates an example co-packaged photonics device 100 (or just device 100), in accordance with at least one embodiment of the present disclosure. The device 100 may include a substrate 105, a driver die 110, a driver device 112, a photonics die 120, a photonics device 122, a bond wire 130, and one or more vias 135.

The substrate 105 may be referred to as a submount and may be aluminum nitride. Alternatively, or additionally, the substrate 105 may be silicon germanium and/or other suitable materials and/or compounds for semiconductor devices. The substrate 105 may be operable to support one or more various dies and/or devices affixed thereon, such as the driver die 110, the driver device 112, the photonics die 120, and/or the photonics device 122.

In some instances, the driver die 110 and the photonics die 120 may be mounted on the substrate 105 and may be arranged such that the driver die 110 may be adjacent to the photonics die 120. In such arrangement, the driver device 112 may be adjacent to the photonics device 122. As illustrated in FIG. 1, the bond wire 130 may electrically couple the driver device 112 and the photonics device 122. A length of the bond wire 130 may be shortened relative to prior approaches such that the photonics device 122 may be treated as a parasitic inductor relative to the driver device 112. In some instances, the length of the bond wire 130 may be shorter than one wavelength of an electrical signal between the driver device 112 and the photonics device 122, which may contribute to the photonics device 122 being treated as a parasitic inductor relative to the driver device 112.

In some instances, the driver die 110 and/or the photonics die 120 may include the vias 135 that may be used to support electrical connections. For example, the driver die 110 may include the vias 135 that may facilitate an electrical connection between one or more ground circuits disposed on a top portion of the driver die 110 with one or more circuits disposed on a bottom portion of the driver die 110. Alternatively, or additionally, the vias 135 may be used as a communication channel to electrically connect the driver device 112 with the photonics device 122, such that the bond wire 130 may be removed from the device 100. For example, in instances in which a distance between the driver device 112 and the photonics device 122 satisfies a threshold

Co-packaging the driver device 112 and the photonics device 122 may also reduce the amount of voltage needed to be supplied by the driver device 112 to drive the photonics device 122 as the resistances that were in prior approaches (e.g., impedance in the transmission line, losses in the matching resistor, etc.) may be reduced and/or eliminated, which may result in power savings in the device 100 relative to the prior approaches. Alternatively, or additionally, the driver device 112 and the photonics device 122 may reduce or remove the transmission line impedance that may have been previously included in prior approaches. For example, an electrical signal from the driver device 112 to the photonics device 122 may be transmitted using the bond wire 130 (which may be shortened relative to prior approaches due to the adjacency of the driver device 112 and the photonics device 122) or the vias 135 may reduce or remove the length a signal transmitted from the driver device 112 to the photonics device 122, resulting in a reduced or removed impedance associated with the transmission line.

In some instances, the driver device 112 may be a digital signal processor. Alternatively, or additionally, the driver device 112 may include a digital signal processor. In these and other embodiments, the driver device 112 may be implemented based on a desired signal to drive the photonics device 122. For example, the photonics device 122 may include an intrinsic impedance and the driver device 112 may be tuned to drive the photonics device 122 at the intrinsic impedance. As the driver device 112 matches the intrinsic impedance of the photonics device 122, a bias current that may have been previously associated with the matching resistor may be reduced or removed, as the matching resistor is removed due to the co-packaging of the driver device 112 and the photonics device 122.

Alternatively, or additionally, the driver device 112 may be tunable relative to the photonics device 122, which may cause the driver device 112 to tune the electrical signal to the photonics device 122 to be closer to the intrinsic impedance of the photonics device 122. For example, the driver device 112 may be tunable to be more or less capacitive and/or more or less resistive to better match the intrinsic impedance of the photonics device 122. The driver device 112 may be tunable such that the output of the driver device 112 may support a range of impedances that may be included in the photonics device 122 (and/or other photonics devices that the driver device 112 may be used with).

In some instances, the photonics device 122 may be an electro-absorptive modulated laser (EML) that may include an electro-absorptive (EA) and a distributed feedback (DFB) laser. Alternatively, or additionally, the photonics device 122 may be other types of photonics devices, which may include a Mach-Zehnder interferometer. In these and other embodiments, the photonics device 122 may include a temperature sensor and/or may capable of determining a temperature associated with the photonics device 122. Alternatively, or additionally, other components in the device 100 may be operable to determine a temperature within the device 100, such as a temperature associated with the photonics device 122.

In some instances, one or more components in the device 100 may be operable to sense currents in the components. For example, the driver device 112 and/or the photonics device 122 may individually be operable to sense a current associated with an electrical signal transmitted and/or received by the said device.

Modifications, additions, or omissions may be made to the device 100 without departing from the scope of the present disclosure. For example, in some instances, the device 100 may be implemented as a flip chip, may be implemented using a complementary metal-oxide semiconductor, and/or any other configuration to drive the photonics device 122. In some instances, an amplifier may be used with the driver device 112 in transmitting an electrical signal to the photonics device 122. Alternatively, or additionally, the bond wires between the driver device 112 and the photonics device 122 may be completely removed and/or replaced by the vias 135 included in the driver die 110 and/or the photonics die 120.

In another example, the designations of different elements in the manner described is meant to help explain concepts described herein and is not limiting. Further, the device 100 may include any number of other elements or may be implemented within other systems or contexts than those described. For example, any of the components of FIG. 1 may be divided into additional or combined into fewer components.

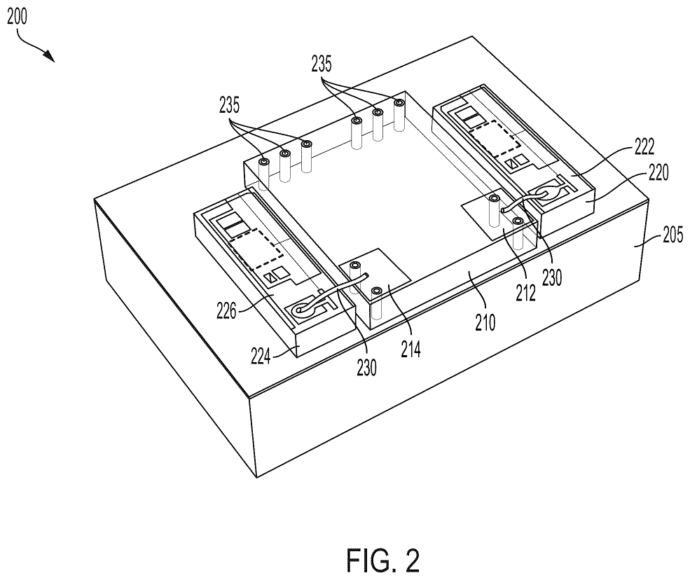

FIG. 2 illustrates an example co-packaged photonics device 200 (or just device 200), in accordance with at least one embodiment of the present disclosure. The device 200 may include a substrate 205, a driver die 210, a first driver device 212, a second driver device 214, a first photonics die 220, a first photonics device 222, a second photonics die 224, a second photonics device 226, bond wires 230, and one or more vias 235.

The device 200 may be the same or similar as the device 100 of FIG. 1, with the exception that the device may include an additional die and photonics device (the second photonics die 224 and the second photonics device 226, respectively) and the driver die 210 may support the first driver device 212 and the second driver device 214. The first driver device 212 may be operable to drive the first photonics device 222 and the second driver device 214 may be operable to drive the second photonics device 226. In some instances, the driver die 210 may be adjacent to both the first photonics die 220 and the second photonics die 224. For example, the first photonics die 220 may be disposed adjacent to a first side of the driver die 210 and the second photonics die 224 may be disposed adjacent to a second side of the driver die 210, where the second side may be opposite the first side.

In some instances, the first driver device 212 and the second driver device 214 may individually include a driver type. The driver type may correspond to the photonics device, or a photonics device that may be operated by a particular driver type. For example, the first driver device 212 may have a first driver type and may be operable to drive the first photonics device 222 and the second driver device 214 may have a second driver type and may be operable to drive the second photonics device 226.

In some instances, the driver type associated with the first driver device 212 and the second driver device 214 may be the same. For example, in instances in which the first photonics device 222 and the second photonics device 226 are substantially similar, the driver type associated with the first driver device 212 and the second driver device 214 may be the same. In another example, in instances in which the first photonics device 222 and the second photonics device 226 are different, but have similar intrinsic impedances, the driver type associated with the first driver device 212 and the second driver device 214 may be the same. In another example, in instances in which the first photonics device 222 and the second photonics device 226 are different and have different intrinsic impedances, the driver type associated with the first driver device 212 and the second driver device 214 may be the same, where each of the driver devices may be tuned to match the different intrinsic impedances associated with the first photonics device 222 and the second photonics device 226.

Alternatively, or additionally, the driver type associated with the first driver device 212 and the second driver device 214 may differ. For example, in instances in which the first photonics device 222 and the second photonics device 226 are different, the driver type associated with the first driver device 212 and the second driver device 214 may be different from one another. In another example, in instances in which the first photonics device 222 and the second photonics device 226 are substantially the same, but have different intrinsic impedances, the driver type associated with the first driver device 212 and the second driver device 214 may differ from one another.

In some instances, one or more guard rings may be disposed between the first driver device 212 and the second driver device 214, which may limit and/or reduce interference between the first driver device 212 and the second driver device 214. Alternatively, or additionally, the guard rings may be omitted from the device 200 and one or more additional circuits may occupy the space on the driver die 210 that might otherwise be occupied by the guard rings.

Modifications, additions, or omissions may be made to the device 200 without departing from the scope of the present disclosure. For example, in some instances, the designations of different elements in the manner described is meant to help explain concepts described herein and is not limiting. Further, the device 200 may include any number of other elements or may be implemented within other systems or contexts than those described. For example, any of the components of FIG. 2 may be divided into additional or combined into fewer components.

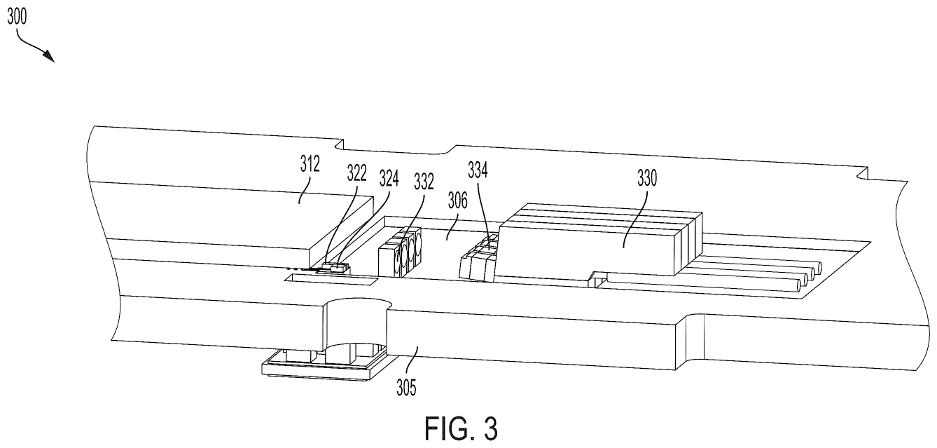

FIG. 3 illustrates an example co-packaged photonics device 300 (or just device 300), in accordance with at least one embodiment of the present disclosure. The device 300 may include a substrate 305, a core 306, a driver device 312, a photonics device 322, an interconnect die 324, a fiber array unit 330, a lens array 332, and an isolator 334.

In some instances, at least the substrate 305, the driver device 312, and/or the photonics device 322 may be the same or similar as the substrate 105, the driver device 112, and/or the photonics device 122 of FIG. 1, such that the components of the device 300 may be operable to perform the same or similar operations as described relative to the device 100 of FIG. 1, unless otherwise disclosed. Further, similar to the disposition of the driver device 112 and the photonics device 122 in FIG. 1, the driver device 312 and the photonics device 322 may be disposed adjacent to one another.

In some instances, the fiber array unit 330, the lens array 332, and the isolator 334 may be used to transmit and/or receive optical signals that may be the optical transmissions described herein. For example, the fiber array unit 330 may be a one- or two-dimensional array of optical fibers that may be used to transmit an optical signal or receive an optical signal transmitted from another device. The isolator 334 may contribute to reducing noise in optical signals, such as reflections that may occur in the optical fibers.

In some instances, the photonics device 322 may be attached to the substrate 305 and the driver device 312 may be attached to the substrate 305 adjacent to the photonics device 322. Alternatively, or additionally, the driver device 312 may be attached to the substrate 305 and the photonics device 322 may be attached to the core 306. In these and other embodiments, the driver device 312 may be adjacent to the photonics device 322 and may be configured to drive the photonics device 322 as described herein.

In some instances, the substrate 305 and the core 306 may be the same material. Alternatively, or additionally, the core 306 may be a different material from the substrate 305. For example, the core 306 may be a glass substrate or ceramic substrate and the substrate 305 may be one or more layers of organic substrate. In some instances, the substrate 305 may be a printed circuit board.

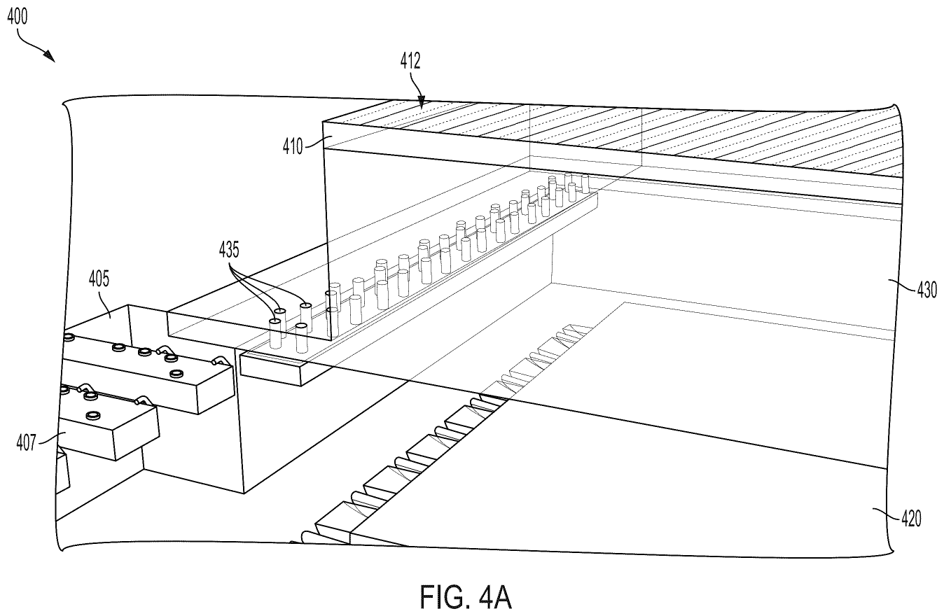

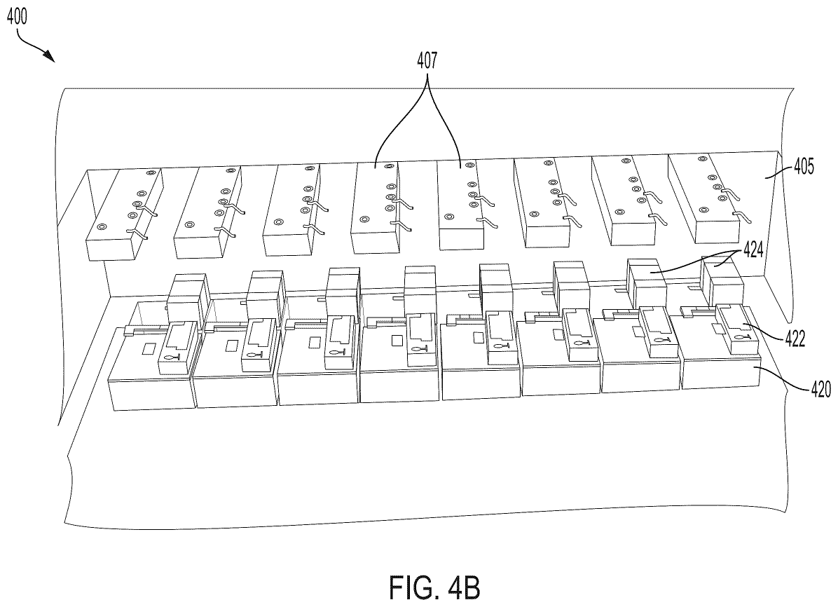

FIG. 4A illustrates an example co-packaged photonics device 400 (or just device 400), in accordance with at least one embodiment of the present disclosure. FIG. 4B illustrates another view of the device 400 of FIG. 4A, in accordance with at least one embodiment of the present disclosure. The device 400 may include a substrate 405, a driver die 410, a driver device 412, a photonics die 420, a photonics device 422, and an interposer 430. The substrate 405 may include one or more first protrusions 407. The photonics device 422 may include one or more second protrusions 424. The interposer 430 may include one or more vias 435.

In some instances, at least the substrate 405, the driver die 410, the driver device 412, the photonics die 420, and the photonics device 422 may be the same or similar as the substrate 105, the driver die 110, the driver device 112, the photonics die 120, and the photonics device 122 of FIG. 1, such that the components of the device 400 may be operable to perform the same or similar operations as described relative to the device 100 of FIG. 1, unless otherwise disclosed. Further, similar to the disposition of the driver device 112 and the photonics device 122 in FIG. 1, the driver device 412 and the photonics device 422 may be disposed adjacent to one another (which may or may not include the interposer 430 disposed between the driver device 412 and the photonics device 422).

In some instances, the substrate 405 may be a printed circuit board. Alternatively, or additionally, the substrate 405 may be composed of one or more layers. For example, the substrate 405 may include a first layer at a core portion thereof, and one or more additional layers added thereon. For example, the core of the substrate 405 may be a glass or glass-like materials, and may include one or more layers of organic substrate layered thereon. The interposer 430 may be referred to as an electrical routing interface, as electrical signals between the driver device 412 and the photonics device 422 may be routed through the interposer 430.

In some instances, at least the photonics device 422 may be disposed in a cavity within the substrate 405, where the cavity may be laser-cut in the substrate 405. Alternatively, or additionally, the photonics device 422, the interposer 430, and/or the driver device 412 may be partially or fully disposed in the laser-cut cavity. In some instances, the interposer 430 may be disposed on a ledge adjacent to the laser-cut cavity, such that the photonics device 422 may be within the laser-cut cavity and the driver device 412 may be without the laser-cut cavity. Alternatively, or additionally, in instances in which the interposer 430 is not present in the device 400, the driver device 412 may be disposed on a ledge adjacent to the laser-cut cavity, such that the photonics device 422 may be within the laser-cut cavity. In these and other embodiments, the contact of the interposer 430 and/or the driver device 412 with the ledge in the substrate 405 may distribute the load to the interposer 430 and/or the driver device 412 such that mechanical stress to the photonics device 422 may be reduced or eliminated.

In some instances, a depth of the ledge in the substrate 405 may be complementary to a thickness of the interposer 430 (e.g., the thickness of the interposer 430 configured to contact the substrate 405 may be the same or similar as a thickness of the offset of the ledge in the substrate 405). Alternatively, or additionally, the depth of the ledge in the substrate 405 may be complementary to a thickness of the driver device 412.

In some instances, the interposer 430 may be made of glass, silicon, aluminum nitride, and/or other similar materials. The vias 435 in the interposer 430 may facilitate one or more electrical connections between the photonics device 422 (e.g., photodiodes in the photonics device 422) and the driver device 412. Alternatively, or additionally, one or more vias may be disposed in the interposer 430 adjacent to the ledge of the substrate 405, which may facilitate a signal flow to various components in the substrate 405. In some embodiments, the thickness of the interposer 430 and/or the arrangement of the interposer 430 on the ledge of the substrate 405 may increase the rigidity of the device 400 and/or the photonics device 422 and/or may reduce mechanical stress to the photonics device 422 such that stresses to the optical fiber may not cause a corresponding issue to the optics within the photonics device 422.

In some instances, the substrate 405 may include one or more first protrusions, as illustrated in FIG. 4B. Alternatively, or additionally, the photonics device 422 may include one or more second protrusions that may be complementary to the first protrusions of the substrate 405. For example, the substrate 405 and the photonics device 422 may be arranged such that the first protrusions and the second protrusions may be interlaced with one another. In some embodiments, the first protrusions may be laser cut in the substrate 405, such that the size of the first protrusions may be substantially the same as the second protrusions of the photonics device 422. As such, a distance between the substrate 405 and the photonics device 422 may be electrically small, such as tens to hundreds of microns in length. For example, a gap between the first protrusions and the second protrusions may be less than one hundred microns. Alternatively, or additionally, the electrical connection between the substrate 405 and the photonics device 422, as described, may be electrically connected using one or more bond wires and may not implement vias (e.g., as described relative to the interposer 430) as the distance between the substrate 405 and the photonics device 422 may be electrically small.

In some instances, the photonics device 422 may be configured to transmit and/or receive optical signals. For example, the photonics device 422 may include one or more photodiodes and/or one or more photodetectors. In some instances, the transmission and reception of the optical signals may be used to perform an alignment of the photonics device 422 and/or may be used determine and/or tune one or more characteristics associated with the device 400. For example, the output of the photonics device 422 may be optimized by the driver device 412 adjusting a bias associated with the photonics device 422. For example, the driver device 412 may determine a bias of the photonics device 422 relative to a current curve associated with the optical signals of the photonics device 422. Alternatively, or additionally, adjustments to the current curve may be made in view of the response to optical data transmitted and/or received by the driver device 412. For example, in portions of the current curve that are nonlinear (e.g., as detected by transmission and/or receptions of optical data), the current curve may be linearized using the optical data.

In another example, the driver device 412 may be used as a reflection detector, which as described, may be used to perform an alignment of the components in the device 100. Alternatively, or additionally, the driver device 412 may be used as a network analyzer by measuring and/or determining a time domain response based on the transmitted and/or received optical signals. Further, calibration techniques may be applied to the transmitted and/or received optical signals to separate the different signals, which may improve the operability of the driver device 412 as a network analyzer.

In another example, driver device 412 may be used to support bidirectional optical signals on a single optical fiber. For example, the single optical fiber may be used in duplex, where the single optical fiber may support transmitting an optical signal and/or receiving an optical signal. Further, the driver device 412 may be operable to perform signal processing to the optical signal which may be used to remove noise in the optical signal (which may include removing portions of the transmitted signal from the received signal, e.g., a reflection). In such an arrangement, half of the optical fibers may be used relative to a non-duplex arrangement and/or a single transceiver device (such as the photonics device 422) may be used in place of a transmitter and a receiver, thus simplifying the system and/or reducing the number of components that may be included in the device 100.

In an example embodiment, a system may include a printed circuit board that may include a cavity and a ledge disposed adjacent to the cavity. The printed circuit board may have first multiple protrusions. The system may also include an electrical routing interface that may be configured to cover at least a portion of the cavity while in contact with the ledge. The electrical routing interface may include one or more vias and the electrical routing interface may have a first surface and a second surface opposite the first surface. The system may also include a photonics device that may have second multiple protrusions that may be complementary to the first multiple protrusions. The photonics device may be coupled to the electrical routing interface on the first surface such that the photonics device may be disposed within the cavity. Alternatively, or additionally, the second multiple protrusions may be interlaced with the first multiple protrusions. The system may also include a photonics driver that may be coupled to the electrical routing interface on the second surface. The photonics driver may be operable to drive the photonics device by transmitting an electrical signal to the photonics device through the one or more vias.

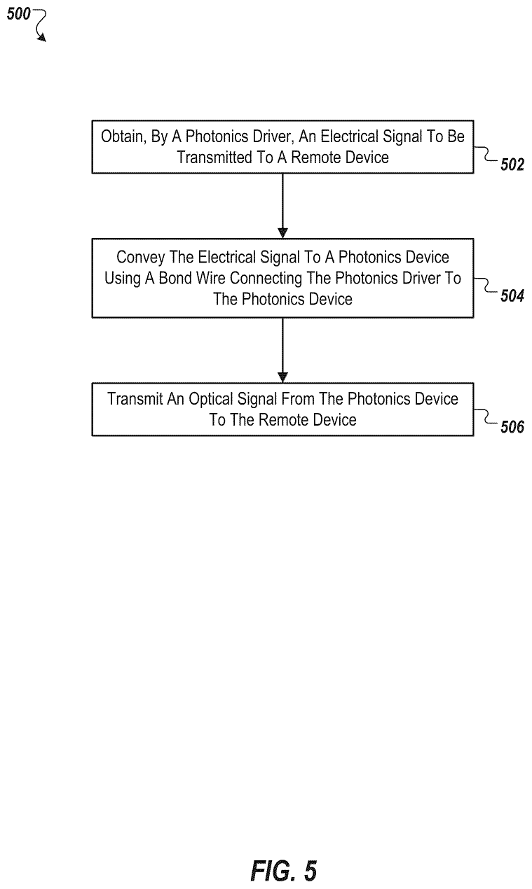

FIG. 5 illustrates a flowchart of an example method 500 of signal transmission using a co-packaged photonics device, in accordance with at least one embodiment of the present disclosure. The method 500 may be performed by processing logic that may include hardware (circuitry, dedicated logic, etc.), software (such as is run on a general purpose computer system or a dedicated machine), or a combination of both, which processing logic may be included in any computer system or device such as the device 100 of FIG. 1.

For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification may be capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

At block 502, an electrical signal may be obtained by a photonics driver to be transmitted to a remote device.

At block 504, the electrical signal may be conveyed to a photonics device using a bond wire connecting the photonics driver to the photonics device. The photonics driver and the photonics device may be adjacently attached to a substrate and the photonics driver may be configured to drive the photonics device at an intrinsic impedance of the photonics device.

At block 506, an optical signal may be transmitted from the photonics device to the remote device.

Modifications, additions, or omissions may be made to the method 500 without departing from the scope of the present disclosure. For example, a second optical signal may be received by the photonics device where the optical signal and the second optical signal may be utilized to detect signal reflection in a system. Alternatively, or additionally, the optical signal and the second optical signal may be utilized to perform an alignment of components in the system. In another example, a second optical signal may be received by the photonics device and in instances in which the photonics driver is a network analyzer, the photonics driver may determine a time domain response by using the optical signal and the second optical signal. In another example, a second optical signal may be received by the photonics device where the optical signal and the second optical signal may be transmitted on a single optical fiber. The photonics driver may be configured to remove a reflection of the optical signal from the second optical signal.

In another example, the designations of different elements in the manner described is meant to help explain concepts described herein and is not limiting. Further, the method 500 may include any number of other elements or may be implemented within other systems or contexts than those described.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although implementations of the present disclosure have been described in detail, various changes, substitutions, and alterations could be made hereto without departing from the spirit and scope of the present disclosure.

What is claimed is:

1. A co-packaged photonics device, comprising:
a photonics device having an intrinsic impedance and attached to a substrate; and
a photonics driver disposed on a driver die and attached to the substrate adjacent to the photonics device, the photonics driver comprising one or more electrical connections with the photonics device, wherein the photonics driver is configured to drive the photonics device at the intrinsic impedance.

2. The co-packaged photonics device of claim 1, further comprising a second photonics driver attached to the substrate adjacent to a second photonics device, wherein one or more guard rings separate the photonics driver from the second photonics driver.

3. The co-packaged photonics device of claim 2, where the photonics driver includes a first driver type and the second photonics driver includes a second driver type, and the first driver type differs from the second driver type.

4. The co-packaged photonics device of claim 2, the photonics device is on a first side of the driver die and the second photonics device is on a second side of the driver die opposite the first side.

5. The co-packaged photonics device of claim 1, further comprising a digital signal processor paired with the photonics driver to drive operations of the photonics device.

6. The co-packaged photonics device of claim 1, wherein a bond wire length electrically coupling the photonics device and the photonics driver is shorter than one wavelength of an electrical signal passed between the photonics device and the photonics driver.

7. The co-packaged photonics device of claim 1, wherein a distance between the photonics device and the photonics driver satisfies a threshold such that an electrical coupling between the photonics device and the photonics driver is made without a bond wire.

8. The co-packaged photonics device of claim 1, wherein a configuration of the photonics driver is tuned based on one or more characteristics of the photonics device.

9. The co-packaged photonics device of claim 1, wherein an output of the photonics device is optimized by the photonics driver adjusting a bias associated with the photonics device.

10. The co-packaged photonics device of claim 1, wherein the photonics device is an electro-absorptive modulated laser.

11. The co-packaged photonics device of claim 1, wherein the driver die comprises one or more vias that are used as a communication channel between the photonics driver and one or more circuits.

12. A co-packaged photonics device, comprising:
a substrate;
a first die attached to the substrate having a first photonics device disposed on the first die, the first photonics device having a first intrinsic impedance;
a second die attached to the substrate having a second photonics device disposed on the second die, the second photonics device having a second intrinsic impedance; and
a third die attached to the substrate and adjacent to the first die and the second die, the third die having a first photonics driver and a second photonics driver disposed thereon, wherein the first photonics driver is configured to drive the first photonics device at the first intrinsic impedance and the second photonics driver is configured to drive the second photonics device at the second intrinsic impedance.

13. The co-packaged photonics device of claim 12, wherein one or more guard rings are disposed between the first photonics driver and the second photonics driver.

14. The co-packaged photonics device of claim 12, wherein the first photonics driver is a first driver type and the second photonics driver is a second driver type, and the first driver type is the same as the second driver type.

15. The co-packaged photonics device of claim 12, wherein a first configuration of the first photonics driver is tuned based on one or more characteristics of the first photonics device and a second configuration of the second photonics driver is tuned based on one or more characteristics of the second photonics device.

16. The co-packaged photonics device of claim 12, wherein:
a first bond wire length electrically coupling the first photonics device and the first photonics driver is shorter than one wavelength of a first electrical signal passed between the first photonics device and the first photonics driver; and
a second bond wire length electrically coupling the second photonics device and the second photonics driver is shorter than one wavelength of a second electrical signal passed between the second photonics device and the second photonics driver.

17. A method, comprising:
obtaining, by a photonics driver, an electrical signal to be transmitted to a remote device;
conveying the electrical signal to a photonics device using a bond wire connecting the photonics driver to the photonics device, where the photonics driver and the photonics device are adjacently attached to a substrate and wherein the photonics driver is configured to drive the photonics device at an intrinsic impedance of the photonics device; and
transmitting an optical signal from the photonics device to the remote device.

18. The method of claim 17, further comprising receiving, by the photonics device, a second optical signal, wherein the optical signal and the second optical signal are utilized to detect signal reflection in a device and are utilized to perform an alignment of components in the device.

19. The method of claim 17, further comprising receiving, by the photonics device, a second optical signal, wherein the photonics driver is a network analyzer and determines a time domain response by using the optical signal and the second optical signal.

20. The method of claim 17, further comprising receiving, by the photonics device, a second optical signal, wherein the optical signal and the second optical signal are transmitted on a single optical fiber, and the photonics driver is configured to remove a reflection of the optical signal from the second optical signal.
